(19) United States
(12) Patent Application Publication
(10) Pub. No.: US 2025/0066188 A1
(43) Pub. Date: Feb. 27, 2025

(54) MEMS GRATING AND FABRICATION METHOD

(71) Applicant: Northwestern Polytechnical University, Xi’an (CN)

(72) Inventors: Yongqian Li, Xi’an (CN); Datai Hui, Xi’an (CN); Dayong Qiao, Xi’an (CN)

(73) Assignee: Northwestern Polytechnical University, Xi’an (CN)

(21) Appl. No.: 18/504,845

(22) Filed: Nov. 8, 2023

(30) Foreign Application Priority Data
Aug. 24, 2023 (CN) 202311077044X

(51) Int. Cl. B81C 1/00; G02B 5/18

(52) U.S. Cl. CPC B81C 1/00928; G02B 5/1857; B81C 2201/0109; B81C 2201/0133

(57) ABSTRACT

The present disclosure discloses a MEMS grating and a fabrication method. The MEMS grating includes a substrate layer, an insulation layer and a deformable layer. The deformable layer is made of a continuous conductive material, the insulation layer is distributed along transverse intervals on the substrate layer, and a cavity is formed between every two adjacent insulation layers. The deformable layer includes movable grating bars and fixed grating bars. The fixed grating bars are fixedly connected with the insulation layer, and the movable grating bars correspond to the cavities. A plurality of through holes are formed in the movable grating bars. During wet etching, the movable grating bars generate upwards buckling deformation, which increase an initial gap between the movable grating bars and a substrate. An adhesion effect caused by the wet etching is eliminated, which reduces permanent failures caused by the adhesion effect.

### CROSS-REFERENCE TO RELATED APPLICATIONS

The application claims priority to Chinese patent application No. 202311077044X, filed on Aug. 24, 2023, the entire contents of which are incorporated herein by reference.

### TECHNICAL FIELD

The present disclosure belongs to the technical field of MEMS gratings and relates to a MEMS grating and a fabrication method.

### BACKGROUND

A MEMS grating is widely applied to the field of projects such as a projection system, a flat panel display, a laser radar and space optical communication. An existing fabrication process of the MEMS grating is mainly based on surface micromachining and obtains a movable grating structure by depositing a layer of a thin-film material on a substrate, performing targeted selective etching on the thin-film material and then releasing a sacrificial layer of the substrate. An aspect ratio of a MEMS grating device manufactured by using a surface technology is small, a thin film deposited on the substrate generally has a pre-tensile stress, after a sacrificial layer structure is released, a grating structure layer is prone to having a downward sunken deformation, so the movable grating structure is attached to the substrate due to an action of capillary attraction and a hydrogen bond of a liquid, and consequently, permanent failure of the device is caused.

As for an existing grating structure, a silicon dioxide sacrificial layer and a silicon nitride thin-film layer are deposited on a single-crystal silicon substrate in sequence to form a three-layer structure, selective etching is performed on a silicon nitride thin film, and the silicon dioxide sacrificial layer is released to obtain the movable grating structure. The deposited silicon nitride thin film has an initial tensile stress, releasing holes in the silicon nitride thin film are in one-dimensional arrangement along a center line of the movable grating structure, after wet etching is performed, the movable grating structure of the MEMS grating is prone to sinking downwards, then the movable structure adheres to the substrate during releasing, and consequently, failure of the device is caused.

At present, methods for avoiding occurrence of an adhesion phenomenon during machining and releasing of the MEMS grating are: (1) a thickness of the sacrificial layer is increased. The thickened sacrificial layer may increase an initial gap between the movable structure and the substrate, so that the action of the capillary attraction and the hydrogen bond in the liquid is reduced. (2) Surface adhesive energy or an adhesive force is reduced through contact surface modification, such as using a self-assembled monolayer and a surface hydrophobic film. (3) A releasing method and a drying method are changed, and in order to prevent an influence of a liquid surface tension on releasing adhesion, the drying method, a sublimation releasing method, a carbon dioxide supercritical releasing method, a hydrofluoric acid gas phase releasing and the like are performed on the device after the sacrificial layer is released. Problems existing in the above methods are: the increased initial gap may cause reduction of an effective electrostatic force, increasing of an actuation voltage and increasing of overall power consumption of the device; the contact surface modification technology is poor in on-chip consistency and greatly affected by environment humidity in the process; and adhesion can be eliminated remarkably by using the dry release and critical point drying, but a critical point drying device and a hydrofluoric acid gas phase releasing device are high in price and cost and not suitable for large-batch production.

### SUMMARY

An objective of the present disclosure is to solve the problem that adhesion is prone to occurring during releasing of a MEMS grating in the prior art and provide a MEMS grating and a fabrication method.

In order to achieve the above objective, the present disclosure adopts the following technical solutions.

A MEMS grating includes a substrate layer, an insulation layer and a deformable layer, wherein the insulation layer and the deformable layer are arranged at an upper end of the substrate layer in sequence, the deformable layer is a conductive material with a compressive pre-stress, the insulation layer is distributed along transverse intervals on the substrate layer, and a cavity is formed between every two adjacent insulation layers;
the deformable layer includes movable grating bars and fixed grating bars, the fixed grating bars are fixedly connected with the insulation layer, the movable grating bars correspond to the cavities, included angles between the movable grating bars and the side wall of the insulation layer is smaller than or equal to 90°, and the movable grating bars are upwards-buckling camber surfaces; and
a plurality of through holes are formed in the movable grating bars and used for adjusting a compressive pre-stress of the movable grating bars and changing a displacement amount of upwards-buckling of the movable grating bars.

A further improvement of the present disclosure is;
an area ratio of the through holes in the movable grating bars is inversely proportional to the displacement amount caused by a buckling deformation of the movable grating bars.

Each movable grating bar includes a through hole region and a non-through-hole region; and
the through holes are formed in the through hole region, the through hole region is distributed in a middle of the movable grating bar, and the non-through-hole region is distributed on two sides of the through hole region.

A width of each through hole region is smaller than or equal to two thirds of a width of each movable grating bar.

A plurality of columns of through holes are formed in two sides of a center line of each movable grating bar.

Two columns of through holes are formed, and an area of one column of through holes is greater than an area of the other column of through holes.

A plurality of columns of through holes are formed, including a first column of through holes formed in the center line of each movable grating bar, and the other columns of through holes distributed along two sides of the first column of through holes.

An area of the first column of through holes is greater than an area of a column of through holes in any side of the first column of through holes.

A metal reflecting layer is arranged on the deformable layer.

A fabrication method of a MEMS grating includes the following steps:
fabricating an insulation layer on a substrate layer;
fabricating a deformable layer on the insulation layer, wherein the deformable layer is made of a conductive material with a compressive pre-stress;
performing selective etching on the deformable layer to obtain a plurality of through holes; and
wet etching and removing a part of the insulation layer, and after releasing, obtaining movable grating bars and cavities, wherein included angles between the movable grating bars and the side wall of the insulation layer are each smaller than or equal to 90°.

Compared with the prior art, the present disclosure has the following beneficial effects.

The present disclosure discloses the MEMS grating, the deformable layer is arranged at the upper end of the insulation layer, the deformable layer includes the movable grating bars and the fixed grating bars, the movable grating bars have an initial compressive pre-stress, after wet etching, the movable grating bars are caused to generate an upwards-buckling deformation, the initial gap between the movable grating bars and the substrate is increased, a possibility of causing adhesion between the movable grating bars and the substrate is reduced, the buckling deformation may also reduce a possibility of causing a short circuit between the movable grating bars and the substrate under an action of an electrostatic force, meanwhile, a process of causing the deformation of the movable grating bars also increases an elastic restoring force of a structure, an adhesion effect caused after wet etching is effectively prevented and eliminated, permanent failure of a device due to adhesion is avoided, reliability of the device is improved, and an apparatus disclosed by the present disclosure cannot affect performance of the device per se, and not improve power consumption. The through holes may adjust distribution of the compressive pre-stress of the movable grating bars, so the upwards-buckling deformation displacement of the movable grating bars can be controlled, and when distribution positions and forming areas of the through holes are different, the movable grating bars have different surface types in an actuation state, so different light modulation effects are achieved. The area ratio of the through holes may control the buckling displacement, and an initial buckling displacement becomes smaller, so the actuation voltage is reduced. Meanwhile, air in the cavities of the device may be discharged rapidly during working of the MEMS grating by means of arrangement of the plurality of through holes, squeeze film damping during movement is reduced, and a response speed of the MEMS grating is increased.

Further, in the present disclosure, a width occupied by the through hole region is smaller than or equal to two thirds of the width of each movable grating bar, the distribution positions of the through holes are reasonably arranged, the through holes are gathered in a middle region of each movable grating bar, rigidity of a center region of the movable grating bar is small, rigidity of two sides of the movable grating bar is large, and not only is adjustment of the buckling displacement amount of the movable grating bar guaranteed, but also the performance of the MEMS grating may be prevented from being affected.

Further, in the present disclosure, the two columns of through holes are formed, the area of one column of the through holes is greater than the area of the other column of through holes, the center line of each movable grating bar is used as a symmetry point, the areas of the through holes on two sides are different, and the movable grating bar may have different surface types in the actuation state as required, so that the different light modulation effects are achieved.

The present disclosure discloses the fabrication method of the MEMS grating, the plurality of through holes are etched in the deformable layer, a part of the insulation layer is further etched and removed, the movable grating bars and the cavities are obtained after releasing, the deformable layer is made of the conductive material with the compressive pre-stress, after wet etching, each movable grating bar generates the upward and controllable buckling deformation, the buckling deformation amount of the movable grating bar may be adjusted through distribution of the plurality of through holes, the initial gap between the movable grating bar and the substrate is increased, the adhesion effect caused after wet etching is effectively prevented and eliminated, permanent failure of the device caused by adhesion is avoided, the elastic restoring force of the structure is also increased while the movable grating bar generates the deformation, adhesion of the deformable layer and the substrate caused by the capillary attraction during wet etching is prevented, and when the distribution positions and the forming areas of the through holes are different, the movable grating bar may have different surface types in the actuation state, so the different light modulation effects are achieved.

### BRIEF DESCRIPTION OF DRAWINGS

In order to more clearly describe technical solutions of embodiments of the present disclosure, the accompanying drawings needed in the embodiments will be briefly introduced below. It is to be understood that the following accompanying drawings only show some embodiments of the present disclosure and thus are not supposed to be regarded as a limitation on the scope. Those ordinarily skilled in the art may also obtain other related accompanying drawings according to these accompanying drawings without creative work.

FIG. 1 is an explosive view of a grating structure of the present disclosure.

FIG. 2 is a three-dimensional schematic diagram of a grating structure in a non-actuation state of the present disclosure.

FIG. 3 is a schematic structural diagram of an included angle between a movable grating bar and an insulation layer in an embodiment of the present disclosure.

FIG. 4 is a schematic diagram of a function relationship between a width-to-thickness ratio of a deformable layer and a critical buckling stress in an embodiment of the present disclosure.

FIG. 5 is a schematic diagram of a linear function relationship between an area ratio of through holes and a buckling deformation displacement amount of a movable grating bar in an embodiment of the present disclosure.

FIG. 6 is a diagram of distribution of through holes along a center line in an embodiment of the present disclosure.

FIG. 7 is a structural diagram of symmetrical distribution of through holes along two sides of a center line in an embodiment of the present disclosure.

FIG. 8 is a schematic diagram of a grating surface type in a non-actuation state when through holes are symmetrically distributed along two sides of a center line in an embodiment of the present disclosure.

FIG. 9 is a structural diagram of a grating surface type in an actuation state 1 when through holes are symmetrically distributed along two sides of a center line in an embodiment of the present disclosure.

FIG. 10 is a structural diagram of a grating surface type in an actuation state 2 when through holes are symmetrically distributed along two sides of a center line in an embodiment of the present disclosure.

FIG. 11 is a structural diagram of asymmetrical distribution of through holes along two sides of a center line in an embodiment of the present disclosure.

FIG. 12 is a schematic diagram of a grating surface type in a non-actuation state when through holes are asymmetrically distributed along two sides of a center line in an embodiment of the present disclosure.

FIG. 13 is a structural diagram of a grating surface type in an actuation state 1 when through holes are asymmetrically distributed along two sides of a center line in an embodiment of the present disclosure.

FIG. 14 is a structural diagram of a grating surface type in an actuation state 2 when through holes are asymmetrically distributed along two sides of a center line in an embodiment of the present disclosure.

1—Substrate layer; 2—insulation layer; 3—deformable layer; 4—cavity; 5—movable grating bar; 6—fixed grating bar; 7—through hole region; 8—non-through-hole region; 9—through hole.

### DETAILED DESCRIPTION OF THE EMBODIMENTS

In order to make objectives, technical solutions and advantages of the embodiments of the present disclosure clearer, the technical solutions in the embodiments of the present disclosure will be clearly and completely described in the following with reference to the accompanying drawings in the embodiments of the present disclosure. Apparently, the described embodiments are some rather than all of the embodiments of the present disclosure. In general, components of the embodiments of the present disclosure described and illustrated in the accompanying drawings here may be arranged and designed through various configurations.

Thus, the following detailed description of the embodiments of the present disclosure provided in the accompanying drawings is not intended to limit the claimed protection scope of the present disclosure but only to represent selected embodiments of the present disclosure. All other embodiments obtained by those ordinarily skilled in the art based on the embodiments of the present disclosure without making creative efforts fall within the protection scope of the present disclosure.

It is to be noted that the similar reference numerals and letters represent similar items in the following accompanying drawings, so a certain item, when defined in one accompanying drawing, does not need to be further defined and explained in the following accompanying drawings.

In the description of the embodiments of the present disclosure, it needs to be noted that directions or position relations indicated by terms such as “upper”, “lower”, “horizontal” and “inner” are directions or position relations as shown in the accompanying drawings or conventional directions or position relations during use of a product of the present disclosure and are only intended to conveniently describe the present disclosure and concise the description but not to indicate or imply that a referred apparatus or element necessarily has a specific direction or is constructed or operated in a specific direction, so as not to be understood as a limitation on the present disclosure. Besides, terms such as “first” and “second” are only used for distinguishing description instead of being understood as indicating or implying a relative significance.

Besides, a term “horizontal” does not indicate that a component needs to be absolutely horizontal and may slightly tilt. For example, “horizontal” only means “more horizontal” relative to “vertical” and does not indicate that the structure is necessarily completely horizontal but may slightly tilt.

In the description of the embodiments of the present disclosure, it further needs to be noted that unless otherwise clearly specified and limited, terms such as “arrange”, “mount”, “connected” and “connection” should be understood in a broad sense, for example, it may be fixed connection, or detachable connection, or an integrated connection: may be mechanical connection, or electrical connection; and may be direct connection, indirect connection through an intermediate medium, or may be communication in two elements. Specific meanings of the above terms in the present disclosure may be understood by those ordinarily skilled in the art according to specific conditions.

The present disclosure is further described in detail below with reference to the accompanying drawings.

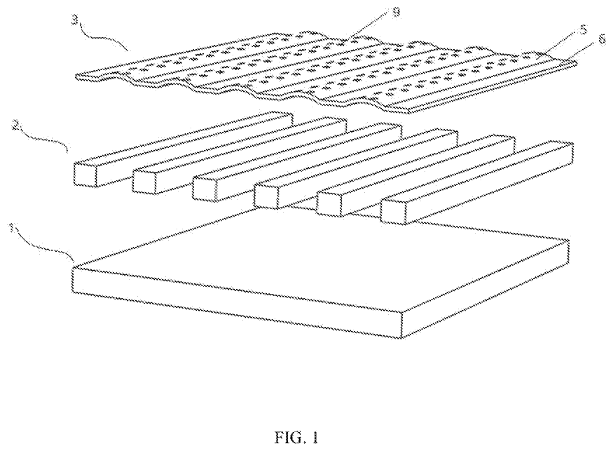

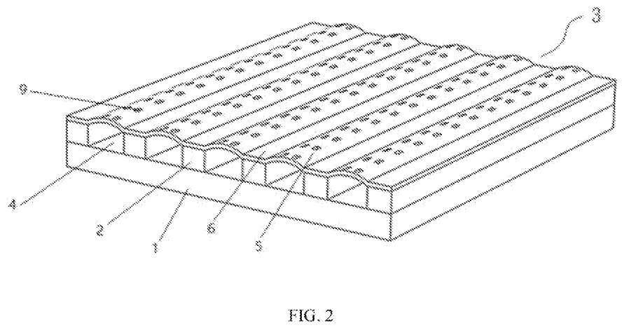

Referring to FIG. 1 to FIG. 2, an embodiment of the present disclosure discloses a MEMS grating. The MEMS grating is mainly composed of a deformable layer, an insulation layer and a substrate layer. In a non-actuation state, a critical buckling stress of the deformable layer with a compressive pre-stress is determined through an aspect ratio of the deformable layer, the critical buckling stress is adjusted through the aspect ratio of the deformable layer so as to be smaller than the compressive pre-stress of a structure, at the moment, a movable grating bar 5 may generate an upward buckling deformation, a displacement amount of the buckling deformation of the deformable layer may be adjusted through an arrangement mode of through holes, adhesion of a movable structure and a substrate in a releasing process is avoided, and failure of a device is prevented. In an actuation state, symmetrical or asymmetrical deformation of the deformable layer may be caused through the distribution mode of the through holes, so as to achieve the different light modulation modes; meanwhile, specially arranged through holes may effectively discharge air in cavities of the device, squeeze film damping during movement of the device is reduced, and an objective of the present disclosure is to solve an adhesion effect generated during fabrication of the MEMS grating through the distribution mode of the through holes of the deformable layer and a fabrication technology.

Specifically, following structures are included.

### Embodiment 1

Referring to FIG. 1 to FIG. 2, an embodiment of the present disclosure discloses a MEMS grating, including a substrate layer 1, an insulation layer 2 and a deformable layer 3, wherein the insulation layer and the deformable layer are arranged at an upper end of the substrate layer 1 in sequence, and the deformable layer 3 is made of a continuous conductive material with a compressive pre-stress; the insulation layer 2 is distributed along transverse intervals on the substrate layer 1, and a cavity 4 is formed between every two adjacent insulation layers 2; and the deformable layer 3 includes movable grating bars 5 and fixed grating bars 6, the fixed grating bars 6 are fixedly connected with the insulation layer 2, the movable grating bars 5 correspond to the cavities 4, and a plurality of through holes 9 are formed in the movable grating bars 5.

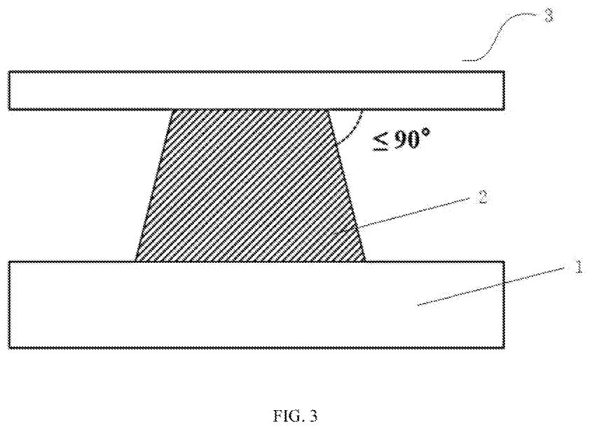

Referring to FIG. 3, in this embodiment, included angles between the movable grating bars 5 and a side wall of the insulation layer 2 are each smaller than or equal to 90°, so as to guarantee upwards buckling of the movable grating bars 5, and the movable grating bars 5 are upwards-buckling camber surfaces.

In this embodiment, the movable grating bars 5 are made of a single-crystal silicon, the insulation layer 2 is made of a silicon dioxide material, the single-crystal silicon and the silicon dioxide are different in hydrophilicity, the single-crystal silicon is a hydrophilic material, silicon dioxide is a non-hydrophilic (hydrophobic) material, an advance speed of a front end of an etch solution along a surface of the single-crystal silicon is greater than an advance speed of a surface of the silicon dioxide, and thus the included angles between the movable grating bars and the side wall of the insulation layer 2 are each smaller than 90°, and upwards-buckling deformation of the movable grating bars 5 is guaranteed.

Further, in this embodiment, the through holes 9 may change a displacement amount of the upwards buckling of the movable grating bars 5, in this embodiment, each cavity 4 corresponds to one movable grating bar 5, an aspect ratio and a critical buckling stress value per se, are in a positive correlation function relationship, a thickness-to-width ratio of the movable grating bar 5 is adjusted, the critical buckling stress of the movable grating bars 5 is adjusted, so the critical buckling stress is smaller than an original compressive pre-stress of a material, the upwards-buckling deformation of the movable grating bars 5 is achieved, and the initial gap and the elastic restoring force may be increased so as to avoid adhesion.

Further, in this embodiment, the width of each movable grating bar 5 refers to a distance between two insulation layers 2.

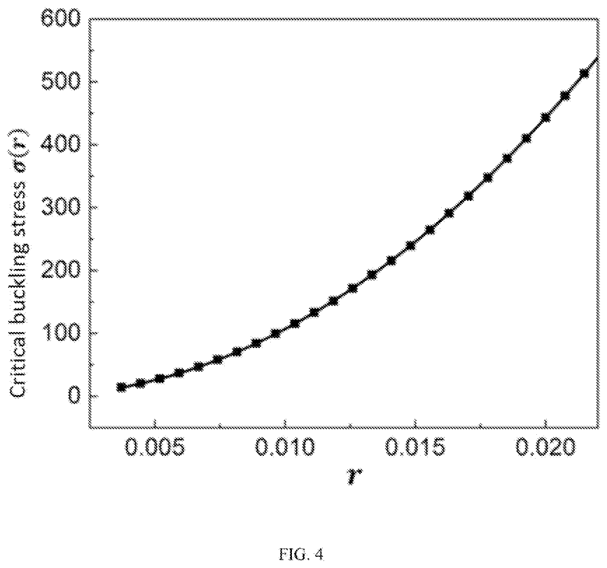

Referring to FIG. 4, in this embodiment, a width-to-thickness ratio r of a section and the critical buckling stress σ of the deformable layer meets a specific power function relationship:

$$σ ( r ) = 1.33 \cdot {10}^{6} \cdot {r}^{2} .$$

When a pre-stress of the movable grating bar 5 is greater than a critical buckling stress, buckling may occur to the movable grating bar 5, and in FIG. 4, the critical buckling stress may be met in a region on and above a curve.

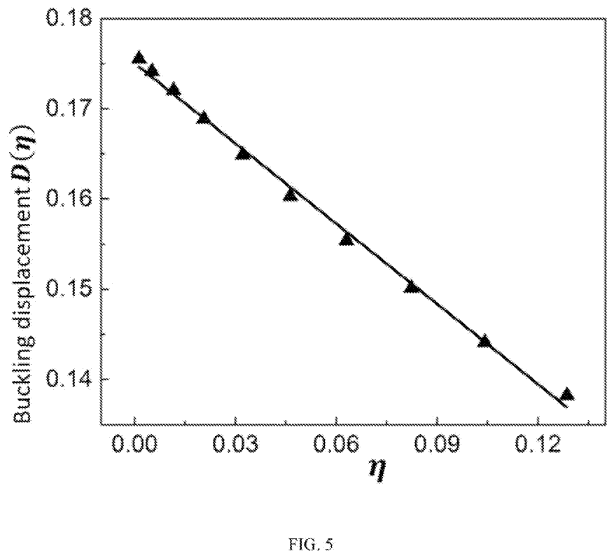

Further, in this embodiment, an area ratio of the through holes 9 to the movable grating bar 5 is inversely proportional to a displacement amount caused by buckling deformation of the movable grating bar 5, and specifically, see FIG. 5, the area ratio n of the through holes 9 and the buckling deformation displacement D of the movable grating bar 5 meet a specific linear function relationship: D(η)=0.175−0.29·η. The area ratio of the through holes 9 is used for adjusting the pre-stress distribution, the deformation displacement of the upwards buckling of the movable grating bar 5 may be controlled, the through holes 9 may reduce an actuation voltage, and the through holes may be adjusted to reduce the squeeze film damping.

In this embodiment, the through holes may be distributed according to different demands, the upwards-buckling deformation displacement of each movable grating bar 5 may be adjusted through the specific distribution modes of the through holes, the adhesion effect caused after wet etching is effectively prevented and eliminated, permanent failure of the device caused by adhesion is avoided, reliability of the device is improved, after wet etching, the upwards buckling may occur to the uneven-rigidity deformable layer with the compressive pre-stress, the deformable layer upwards protrudes in a certain height, the upwards-protruding deformable layer not only increases the initial gap between the deformable layer and the substrate, but also increases the elastic restoring force of the structure, and adhesion of the deformable layer and the substrate caused by capillary attraction during wet etching is prevented.

Further, a through hole structure, serving as a venting channel of the MEMS grating, can rapidly discharge air and reduce squeeze film damping during movement of the device.

### Embodiment 2

This embodiment discloses a specific proportional relation between a total area of through holes and a total area of each movable grating bar, which not only adjusts a displacement amount of buckling deformation of the movable grating bar, but also prevents from affecting performance of a grating, specifically:

An area ratio of the through holes 9 to the movable grating bar 5 is inversely proportional to the displacement amount caused by the buckling deformation of the movable grating bar 5, and in application, this embodiment reasonably controls a forming area of the through holes 9 and adjusts the displacement amount of the upwards buckling deformation of the movable grating bar 5.

### Embodiment 3

A difference between this embodiment and Embodiment 1 lies in that on the basis of Embodiment 1, each movable grating bar 5 includes a through hole region 7 and a non-through-hole region 8; and the through hole region 7 is used for forming through holes 9 and distributed in a middle of the movable grating bar 5, and the non-through-hole region 8 is distributed on two sides of the through hole region 7.

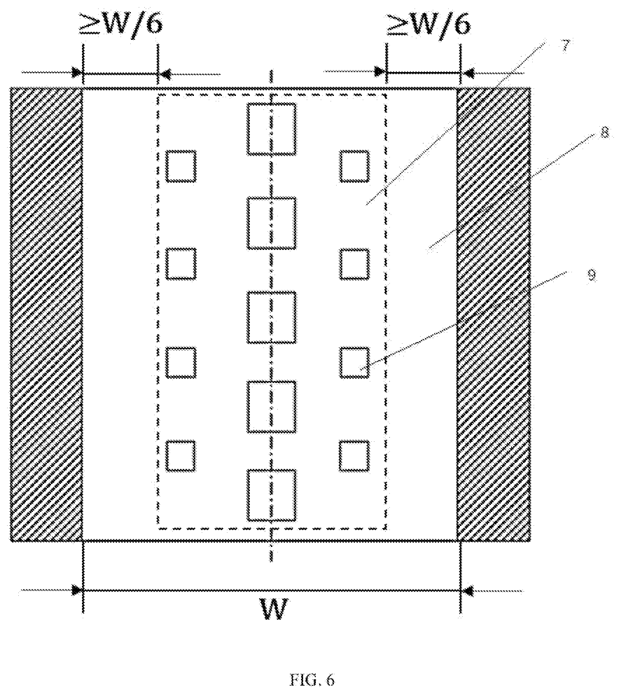

Referring to FIG. 6, further, a width of the through hole region 7 is smaller than or equal to five sixths of a width of the movable grating bar 5, the width in this embodiment refers to a width in a periodic direction of the grating bar, a distance between the through holes and an edge of the movable grating bar is controlled, and a displacement amount of upward protruding of the movable grating bar 5 is adjusted.

### Embodiment 4

A difference between this embodiment and Embodiment 1 lies in that on the basis of Embodiment 1, a specific distribution of through holes is disclosed.

A plurality of columns of through holes 9 are formed in two sides of a center line of each movable grating bar 5.

Further, the through holes 9 may be distributed symmetrically or asymmetrically along the center line of the movable grating bar, and forming areas of the through holes 9 in the two sides of the center line may be the same or not.

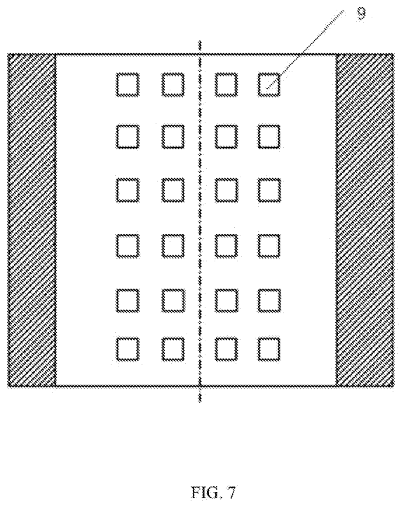

Further, referring to FIG. 7, this embodiment discloses a symmetrical through hole distribution, a total of four columns of through holes are formed, the four columns of through holes 9 are distributed symmetrically along the center line of the movable grating bar 5, and each column of through holes 9 is the same in area.

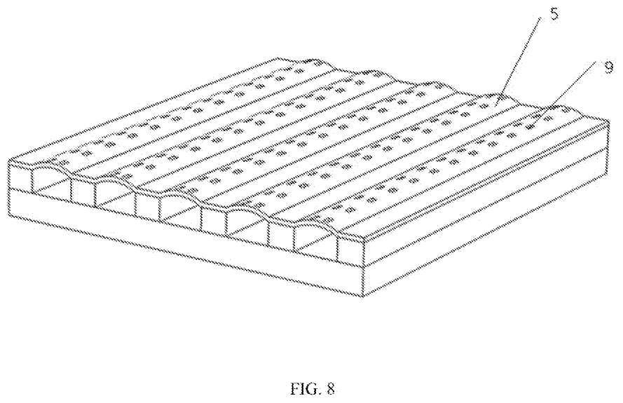

Further, this embodiment further discloses a change process of the movable grating bar 5 under the symmetrical through hole distribution, referring to FIG. 8 to FIG. 10, specifically:
referring to FIG. 8, showing a surface type of the movable grating bar in a non-working state, the movable grating bar 5 has a symmetrical upwards buckling deformation.

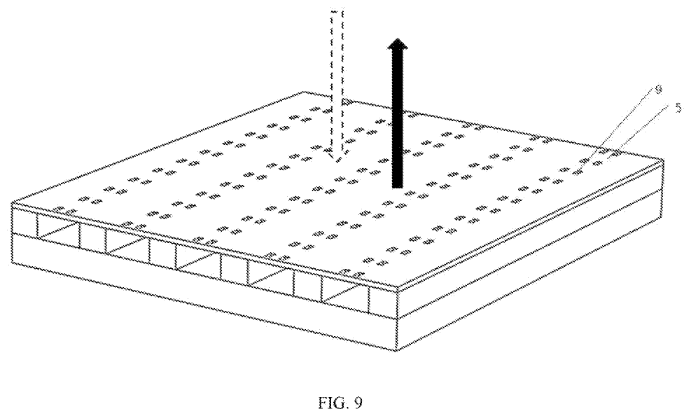

Referring to FIG. 9, showing a working surface type of the movable grating bar, the movable grating bar moves downwards for a certain distance under actuation of an electrostatic force, the movable grating bar and a fixed grating bar are in the same horizontal plane to form a plane reflection surface type, and at the moment, light, after entering a surface of a device, only reflects.

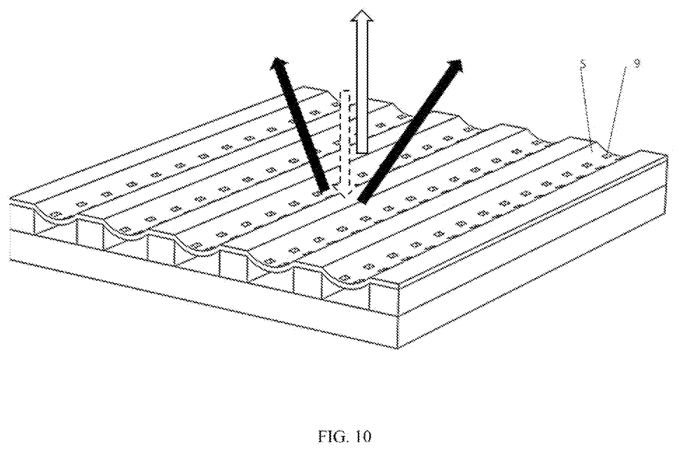

Referring to FIG. 10, showing another working surface type of the movable grating bar, the movable grating bar continues to move downwards for a certain distance under actuation of a greater electrostatic force, a symmetrical downward buckling deformation occurs, and thus the movable grating bar is lower than a horizontal plane of the fixed grating bar to form a one-dimensional phase grating surface type. At the moment, a reflection effect and a diffraction effect occur to light after the light enters the surface of the device, so a modulation effect on a phase of incident light is achieved.

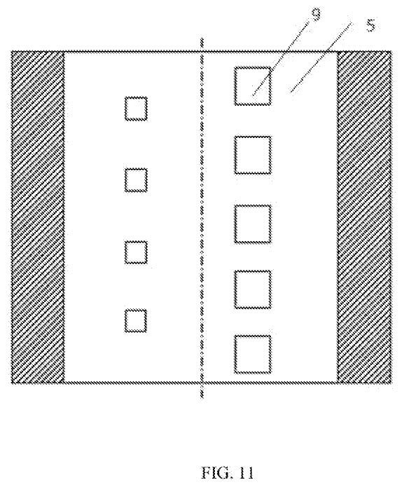

Further, referring to FIG. 11, this embodiment discloses an asymmetrical through hole distribution, two columns of through holes 9 are distributed in the movable grating bar 5, the two columns of through holes 9 are distributed in two sides of a center line of the movable grating bar 5, and an area of one column of through holes 9 is smaller than an area of the other column of through holes 9.

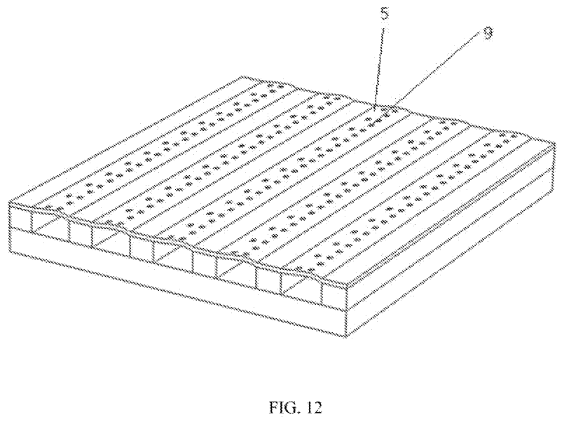

Further, referring to FIG. 12 to FIG. 14, this embodiment further discloses change of the movable grating bar 5 under the asymmetrical through hole distribution, specifically:
referring to FIG. 12, showing a surface type of the movable grating bar in a non-working state, the movable grating bar 5 has an asymmetrical upwards buckling deformation.

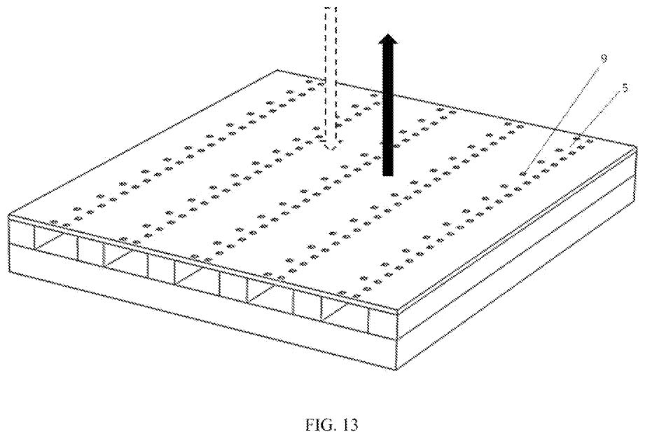

Referring to FIG. 13, showing another working surface type of the movable grating bar, the movable grating bar moves downwards for a certain distance under actuation of an electrostatic force, the movable grating bar and a fixed grating bar are in the same horizontal plane to form a plane reflection surface type, and at the moment, light, after entering a surface of a device, only reflects.

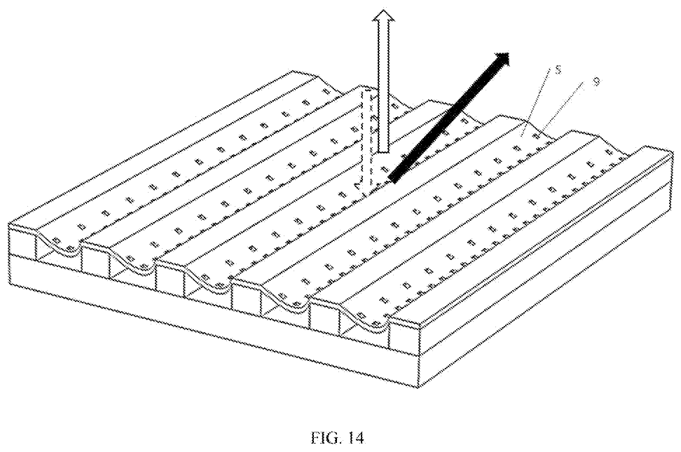

Referring to FIG. 14, showing another working surface type of the movable grating bar, the movable grating bar continues to move downwards for a certain distance under actuation of a greater electrostatic force, an asymmetrical downward buckling deformation occurs, and thus a blazed grating structure is formed. At the moment, a reflection effect and a diffraction effect occur to light after the light enters the surface of the device, so a modulation effect on intensity of incident light is achieved.

### Embodiment 5

A difference between this embodiment and Embodiment 1 lies in that on the basis of Embodiment 1, another distribution mode of through holes is disclosed.

A plurality of columns of through holes 9 are formed, including a first column of through holes 9 formed in a center line of each movable grating bar 5, and the other columns of through holes 9 distributed along two sides of the first column of through holes 9.

Specifically, three columns of through holes 9 are formed, including the first column of through holes in a middle distributed along the center line of the movable grating bar 5, and the two other columns of through holes distributed symmetrically in two sides with the first column of through holes as an axis.

Further, a forming area of the first column of through holes in the middle is greater than a forming area of a column of through holes 9 on any side of the first column of through holes.

Further, in this embodiment, an area and a distribution position of each column of through holes may be adjusted as required.

Rigidity of the movable grating bar in its width direction may be adjusted through different distribution modes of the through holes 9 in the movable grating bar 5, and based on disclosed different distribution modes of the through holes 9 in the embodiment of the present disclosure, a deformable layer has different surface types in an actuation state through the specific distribution modes of the through holes, so as to achieve different light modulation effects. Through symmetrical or asymmetrical distribution design of the through holes along the center line of the movable grating bar, uneven rigidity of the movable grating bar in the width direction is achieved, in the actuation state, symmetrical or asymmetrical deformation may occur to the movable grating bar in its width center line direction, and thus the different working surface types are formed and the different light modulation effects are achieved.

According to actual conditions, air in cavities of a device may be discharged rapidly during working of the MEMS grating by means of the specific distribution modes of the through holes, squeeze film damping during movement is reduced, and a response speed of the MEMS grating is increased.

### Embodiment 6

A difference between this embodiment and Embodiment 1 lies in that on the basis of Embodiment 1, a metal reflection layer is arranged at an upper end of the deformable layer 3 and used for improving reflectivity and light performance of the MEMS grating.

In this embodiment of the present disclosure, widths of the movable grating bar 5 and the fixed grating bar 6 are the same or not.

In this embodiment of the present disclosure, the deformable layer 3 is a uniform conductive material, such as single-crystal silicon or polycrystalline silicon.

This embodiment of the present disclosure discloses:
a thickness of the deformable layer 3 ranges from 1 μm to 5 μm; a sectional area of the through holes 9 formed in the movable grating bar 5 ranges from 5 μm² to 1000 μm²; a length of the movable grating bar 5 ranges from 0.1 mm to 30 mm, and a width of the movable grating bar ranges from 30 μm to 300 μm; and a length of a fixed grating bar 6 ranges from 0.1 mm to 30 mm, and a width of the fixed grating bar ranges from 10 μm to 300 μm;

A metal layer material of an upper surface of the deformable layer 3 is metallic aluminum, silver or gold with a thickness ranging from 50 nm to 200 nm; and a vertical gap from a lower surface of the deformable layer to a substrate layer ranges from 2 μm to 5 μm.

An insulation layer material is a uniform insulation material, such as silicon dioxide with a thickness ranging from 2 μm to 5 μm; a height of a supporting column structure of each insulation layer ranges from 2 μm to 5 μm, a width of a top of a supporting column ranges from 2 μm to 50 μm, and a width of a bottom of the supporting column ranges from 5 μm to 53 μm; and a height of a cavity between insulation layers ranges from 2 μm to 5 μm, a length of the cavity ranges from 0.1 mm to 30 mm, and a width of the cavity ranges from 0.1 mm to 30 mm.

A structure of each insulation layer disclosed in the embodiment of the present disclosure is similar to a column, columns are distributed in a spaced mode, and thus the cavity is formed between every two adjacent columns.

A material of the substrate layer is a uniform conductive material, such as single-crystal silicon with a thickness ranging from 300 μm to 500 μm.

An embodiment of the present disclosure further discloses a fabrication method of a MEMS grating.
Step 1: a silicon dioxide insulation layer with a certain thickness is fabricated on a single-crystal silicon substrate;
step 2: a polycrystalline silicon thin film with a compressive stress is fabricated on the silicon dioxide insulation layer to serve as a deformable layer;
step 3: selective etching is performed on the polycrystalline silicon thin film with an etching depth being greater than or equal to a thickness of the polycrystalline silicon thin film to obtain a through hole structure;
step 4: a part of the silicon dioxide insulation layer is removed, and after releasing, a movable grating bar structure, a supporting column structure in the insulation layer and cavities are obtained, wherein it is guaranteed that included angles between the movable grating bars 5 and the side wall of the insulation layer 2 are each smaller than or equal to 90°;
step 5: a layer of metal thin film is deposited on the deformable layer; and
step 6: optionally, step 5 is added after step 4, and a layer of metal reflection film is deposited on a surface of an SOI wafer device layer.

In the fabrication method disclosed in the present disclosure, a characteristic frequency of the device may be adjusted by controlling releasing time in a process. Relative widths of the movable grating bars and the fixed grating bars after releasing may be adjusted by controlling wet etching time, and as the movable grating bars are independent of one another in the deformable layer, a size of the movable grating bar structure determines the overall characteristic frequency of the device.

According to the MEMS grating obtained through the fabrication method disclosed by the present disclosure, in a fabrication process, a critical buckling stress of the movable grating bars 5 is adjusted, so the critical buckling stress of the movable grating bars 5 is smaller than the compressive pre-stress, it is guaranteed that the each movable grating bar 5 is of an upwards-protruding camber surface structure, then based on adjustment of distribution modes of the through holes, a displacement amount of upwards-buckling deformation of the deformable layer is adjusted, an adhesion effect caused after wet etching is effectively prevented and eliminated, permanent failure of the device caused by adhesion is avoided, reliability of the device is improved, when the distribution modes of the through holes are different, the movable grating bars generate different rigidities in its width direction, and rigidity of a center region of each movable grating bar is small, but rigidity of two sides of the movable grating bar is large. After wet etching, the upwards buckling may occur to the uneven-rigidity deformable layer with the compressive pre-stress, the deformable layer upwards protrudes in a certain height, the upwards-protruding deformable layer not only increases the initial gap between the deformable layer and the substrate, but also increases the elastic restoring force of the structure, and adhesion of the deformable layer and the substrate caused by capillary attraction during wet etching is prevented.

During fabrication, the through holes may be distributed differently, the deformable layer has different surface types in an actuation state through the specific distribution modes of the through holes, so as to achieve different light modulation effects. Through symmetrical or asymmetrical distribution design of the through holes along a center line of each movable grating bar, uneven rigidity of the movable grating bar in the width direction is achieved, in the actuation state, symmetrical or asymmetrical deformation may occur to the movable grating bar in its width center line direction, and thus the different working surface types are formed and the different light modulation effects are achieved.

Air in the cavities of the device may be discharged rapidly during working of the MEMS grating by means of the specific distribution modes of the through holes, squeeze film damping during movement is reduced, and a response speed of the MEMS grating is increased.

The above is only preferred embodiments of the present disclosure and is not intended to limit the present disclosure. The present disclosure may have various variations and changes for those skilled in the art. Any modification, equivalent replacement and improvement made within the spirit and principle of the present disclosure shall fall within the protection scope of the present disclosure.

What is claimed is:

1. A MEMS grating, comprising a substrate layer (1), an insulation layer (2) and a deformable layer (3), wherein the insulation layer (2) and the deformable layer (3) are arranged at an upper end of the substrate layer (1) in sequence, the deformable layer (3) is a conductive material with a compressive pre-stress, the insulation layer (2) is distributed along transverse intervals on the substrate layer (1), and a cavity (4) is formed between every two adjacent insulation layers (2);
the deformable layer (3) comprises movable grating bars (5) and fixed grating bars (6), the fixed grating bars (6) are fixedly connected with the insulation layer (2), the movable grating bars (5) correspond to the cavities (4), included angles between the movable grating bars (5) and a side wall of the insulation layer (2) are each smaller than or equal to 90°, and the movable grating bars (5) are upwards-buckling camber surfaces; and
a plurality of through holes (9) are formed in the movable grating bars (5) and used for adjusting a compressive pre-stress of the movable grating bars (5) and changing a displacement amount of upwards-buckling of the movable grating bars (5).

2. The MEMS grating according to claim 1, wherein an area ratio of the through holes (9) in the movable grating bars (5) is inversely proportional to the displacement amount caused by a buckling deformation of the movable grating bars (5).

3. The MEMS grating according to claim 1, wherein each movable grating bar (5) comprises a through hole region (7) and a non-through-hole region (8); and
the through holes (9) are formed in the through hole region (7), the through hole region (7) is distributed in a middle of the movable grating bar (5), and the non-through-hole region (8) is distributed on two sides of the through hole region (7).

4. The MEMS grating according to claim 3, wherein a width of each through hole region (7) is smaller than or equal to two thirds of a width of each movable grating bar (5).

5. The MEMS grating according to claim 1, wherein a plurality of columns of through holes (9) are formed in two sides of a center line of each movable grating bar (5).

6. The MEMS grating according to claim 5, wherein two columns of through holes (9) are formed, and an area of one column of through holes (9) is greater than an area of the other column of through holes (9).

7. The MEMS grating according to claim 1, wherein a plurality of columns of through holes (9) are formed, including a first column of through holes formed in the center line of each movable grating bar (5), and the other columns of through holes distributed along two sides of the first column of through holes.

8. The MEMS grating according to claim 7, wherein an area of the first column of through holes (9) is greater than an area of a column of through holes (9) in any side of the first column of through holes.

9. The MEMS grating according to claim 1, wherein a metal reflection layer is arranged on the deformable layer (3).

10. A fabrication method of a MEMS grating, comprising the following steps:
fabricating an insulation layer (2) on a substrate layer (1);
fabricating a deformable layer (3) on the insulation layer (2), wherein the deformable layer (3) is made of a conductive material with a compressive pre-stress;
performing selective etching on the deformable layer (3) to obtain a plurality of through holes (9); and
wet etching and removing a part of the insulation layer (2), and after releasing, obtaining movable grating bars(S) and cavities (4), wherein included angles between the movable grating bars (5) and a side wall of the insulation layer (2) are each smaller than or equal to 90°.
